(19) United States
(12) Patent Application Publication
(10) Pub. No.: US 2013/0074926 A1
(43) Pub. Date: Mar. 28, 2013

(54) SOLAR ENERGY CONVERTING DEVICE

(71) Applicant: SHAO-KAI PEI, Tu-Cheng (TW)

(72) Inventor: SHAO-KAI PEI, Tu-Cheng (TW)

(73) Assignee: HON HAI PRECISION INDUSTRY CO., LTD., Tu-Cheng (TW)

(21) Appl. No.: 13/539,491

(22) Filed: Jul. 1, 2012

(30) Foreign Application Priority Data
Sep. 22, 2011 (TW) 100134045

(51) Int. Cl. H01L 31/0232

(52) U.S. Cl. 136/257

(57) ABSTRACT

A solar energy application device, comprising: a solar cell panel comprising a light receiving surface; an electrochromic unit provided on the light receiving surface; and a heat collection device electronically connected to the electrochromic unit; wherein a color of the electrochromic unit changes between a transparent state to a darkened state; wherein in the transparent state of the electrochromic unit, light is incident on the light receiving surface, and the solar cell panel converts the light into electricity; and wherein in the darkened state of the electrochromic unit, the electrochromic unit absorbs the ray to generate heat and then transmits the heat to the heat collection device.

### BACKGROUND

1. Technical Field

The present invention relates to a solar energy converting device.

2. Description of Related Art

A solar cell panel and a solar heat-collection device are two individual devices. So people need those two devices for power-generation and for heat-collecting. This can be very expensive and inconvenient.

Therefore, what is needed is a solar energy converting device which can overcome the above mentioned shortcomings.

### BRIEF DESCRIPTION OF THE DRAWINGS

FIG. 1 is a schematic view of a solar energy application device according to an exemplary embodiment, the solar energy application device including an electrochromic unit.

FIG. 2 is a schematic view showing the color change of the electrochromic unit of FIG. 1.

### DETAILED DESCRIPTION

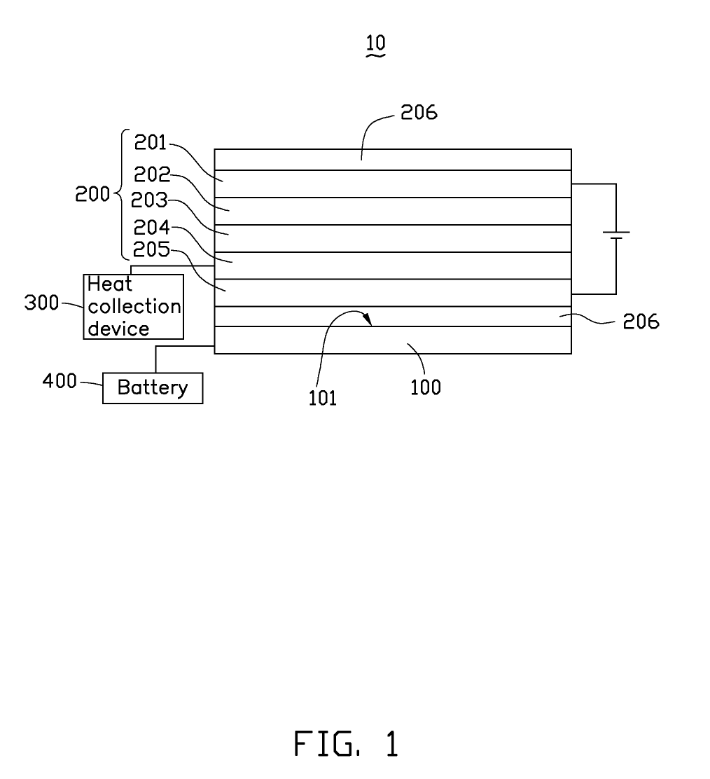

Referring to FIG. 1, a solar energy converting device 10 according to an exemplary embodiment is shown. The solar energy converting device 10 includes a solar cell panel 100, a battery 400 electrically connected to the solar cell panel 100, an electrochromic unit 200 and a heat collection device 300 electrically connected to the electrochromic unit 200. The solar cell panel 100 may be a silicon solar battery plate or a film-type solar cell panel, in one example.

The solar cell panel 100 includes a light receiving surface 101. The electrochromic unit 200 is positioned on the light receiving surface 101. Translucency of the electrochromic unit 200 can be changed from a transparent state (or substantially transparent state) to a darkened state. The darkened state can be black or dark blue, primarily depending on the structure and materials of the electrochromic unit 200. When the electrochromic unit 200 is transparent or substantially transparent, sunlight can pass through the electrochromic unit 200 and hit the light receiving surface 101. Energy of the sun light is eventually stored in the battery 400. When the electrochromic unit 200 is in a darkened state, energy of the sunlight is absorbed by the electrochromic unit 200, causing the electrochromic unit 200 to be heated. The electrochromic unit 200 transmits the heat to the heat collection device 300. The heat collection device 300 stores the heat.

The heat collection device 300 may include a pipe filled with a heat transfer medium. The electrochromic unit 200 is heated by the sunlight, and transmits heat energy to the heat transfer medium in the pipe, so that the temperature of the heat transfer medium is increased in storing the heat energy.

In this embodiment, the electrochromic unit 200 includes a first transparent conductive layer 201, a second transparent conductive layer 205, an ion storage layer 202 used for providing positive ions, an electrolyte layer 203 and an electrochromic layer 204. The second transparent conductive layer 205 is on the bottom of the electrochromic unit 200 and attached to the light receiving surface 101. The first transparent conductive layer 201 is on the top of the electrochromic unit 200 furthest away from the light receiving surface 101. The ion storage layer 202, the electrolyte layer 203 and the electrochromic layer 204 are stacked in that order from the first transparent conductive layer 201 to the second transparent conductive layer 205. The heat collection device 300 can be electronically connected to any layer of the electrochromic unit 200.

The first transparent conductive layer 201 and the second transparent conductive layer 205 transmit negative ions. In this embodiment, the first transparent conductive layer 201 and the second transparent conductive layer 205 are made of indium tin oxide (ITO), transparent conductive plastic, or ITO transparent conductive glass.

The ion storage layer 202 provides positive ions. In this embodiment, the ion storage layer 202 is made of lithium metal, which provides lithium ions (Li⁺).

The electrolyte layer 203 transmits positive ions provided by the ion storage layer 202, for example, H⁺, Li⁺, or Na⁺. The electrolyte in the electrolyte layer 203 is LiClO₄ or LiBF₄, in one example.

The electrochromic layer 204 may be made of organic electrochromic material or inorganic electrochromic material. The organic electrochromic material can be selected from organic low molecular compound or organic polymer, such as polyaniline, viologen, phenazine or the like. The inorganic electrochromic layer can be tungsten trioxide (WO₃) or a metal oxide. In this embodiment, the electrochromic layer 204 is made of WO₃.

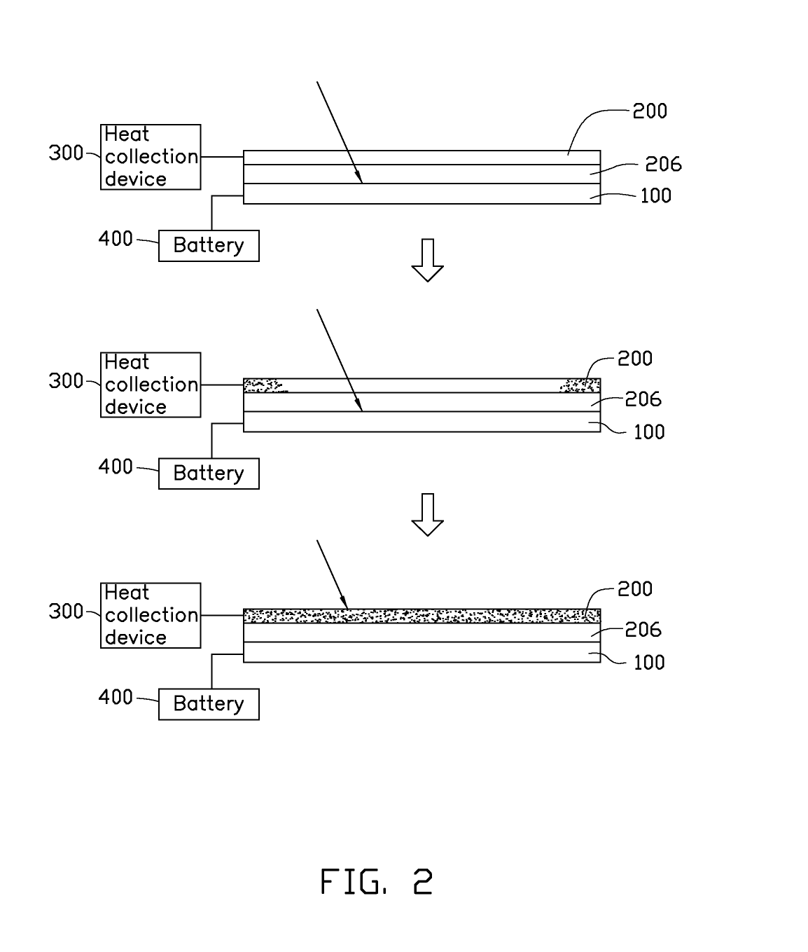

Referring to FIG. 1 and FIG. 2, when the first transparent conductive layer 201 is connected to an anode of a power supply (not shown) and the second transparent conductive layer 202 is connected to a cathode of the power supply, electrons are firstly injected into the electrochromic layer 204. The electrochromic unit 200 becomes electrically neutral, and the positive ions provided by the ion storage layer 202 also move into the WO₃ crystals. The electrochromic unit 200 then enters the darkened state.

Until a voltage is supplied between the first and the second transparent conductive layers 201,205, the electrochromic unit 200 is transparent. Sunlight (shown as arrows in FIG. 2) can strike or fall upon the light receiving surface 101, and the solar cell panel 100 can output power normally.

When a voltage of one to two volts (in one example) is applied between the first and the second transparent conductive layers 201,205, the electrochromic unit 200 will begin to darken gradually. The discoloration area will absorb sunlight and be heated, and the heat will be transmitted to the heat collecting device 300. When the applied voltage is about 1.2 volts, the electrochromic unit 200 is so darkened as to be opaque. The change from transparent to opaque takes about ten seconds. If the voltage is maintained at about 1.2 volts, but the voltage polarity is reversed, the electrochromic unit 200 will return from darkened to colorless (transparent). If the electrochromic unit 200 is darkened, and the supplied voltage is constant, the darkened state can be maintained for about 600 seconds.

If the electrochromic layer 204 is made of inorganic electrochromic material, as the inorganic electrochromic material requires ion implantation into the lattice, the injection speed is slow. Changes of the state from transparent to darkened is thus slow. Using this characteristic, it can achieve the purpose of heat collecting and power generating at the same time.

If the electrochromic layer 204 is made of organic electrochromic material, the chemical reaction speed will be fast and the transition state is brief. It can switch between the two states of heat collecting and electrical-power generating rapidly.

An anti-reflection layer 206 can be provided between the electrochromic unit 200 and the light receiving surface 101. The anti-reflection layer 206 is directly positioned on the light receiving surface 101. The electrochromic unit 200 is directly positioned on the anti-reflection layer 206. The anti-reflection layer 206 is used for improving the light absorption rate. Another anti-reflecting layer 206 can also be directly provided on the electrochromic unit 200.

The solar energy converting device 10 achieves the purposes of electrical-power generation and heat collection in a single device, by means of the electrochromic unit 200.

Even though numerous characteristics and advantages of the present embodiments have been set fourth in the foregoing description, together with details of the structures and functions of the embodiments, the disclosure is illustrative only and changes may be made in details, especially in the matters of shape, size, and the arrangement of parts within the principles of the disclosure to the full extent indicated by the broad general meaning of the terms in which the appended claims are expressed.

What is claimed is:

1. A solar energy application device, comprising:
a solar cell panel comprising a light receiving surface;
an electrochromic unit provided on the light receiving surface; and
a heat collection device electrically connected to the electrochromic unit;
wherein a color of the electrochromic unit changes between a transparent state to a darkened state;
wherein in the transparent state of the electrochromic unit, light is incident on the light receiving surface, and the solar cell panel converts the light into electricity; and
wherein in the darkened state of the electrochromic unit, the electrochromic unit absorbs the light to generate heat and transmits the heat to the heat collection device.

2. The solar energy application device as claimed in claim 1, wherein the electrochromic unit comprises a first transparent conductive layer, an ion storage layer for providing positive ions, an electrolyte layer, an electrochromic layer and a second transparent conductive layer stacked in sequence.

3. The solar energy application device as claimed in claim 2, wherein the first and the second transparent conductive layer are made of transparent conductive glass of indium tin oxide.

4. The solar energy application device as claimed in claim 2, wherein the ion storage layer is a lithium metal layer for providing lithium ions.

5. The solar energy application device as claimed in claim 2, wherein the electrochromic layer is made of organic electrochromic or inorganic electrochromic materials.

6. The solar energy application device as claimed in claim 5, wherein the organic electrochromic material is polyaniline.

7. The solar energy application device as claimed in claim 5, wherein the inorganic electrochromic material is WO₃.

8. The solar energy application device as claimed in claim 1, wherein the electrochromic unit changes its color state when a voltage is applied to the electrochromic unit.

9. The solar energy application device as claimed in claim 1, wherein the solar cell panel is silicon solar battery plate or a film type solar cell panel.

10. The solar energy application device as claimed in claim 1, wherein the solar energy application device further comprising an antireflection layer between the electrochromic unit and the solar cell panel.
